(19) United States
(12) Patent Application Publication
(10) Pub. No.: US 2014/0175412 A1
(43) Pub. Date: Jun. 26, 2014

(54) ORGANIC LUMINESCENT DISPLAY DEVICE AND METHOD OF MANUFACTURING AT ORGANIC LUMINESCENT DISPLAY DEVICE

(71) Applicant: Japan Display Inc., Tokyo (JP)

(72) Inventors: Hiroshi OOOKA, Tokyo (JP); Yuuko MATSUMOTO, Tokyo (JP); Takeshi OOKAWARA, Tokyo (JP); Kohei TAKAHASHI, Tokyo (JP); Hirotsugu SAKAMOTO, Tokyo (JP)

(73) Assignee: Japan Display Inc., Tokyo (JP)

(21) Appl. No.: 14/133,882

(22) Filed: Dec. 19, 2013

(30) Foreign Application Priority Data
Dec. 20, 2012 (JP) 2012-278537

(51) Int. Cl. H01L 51/56; H01L 51/50

(52) U.S. Cl. CPC H01L 51/56; H01L 51/5012
USPC 257/40; 438/34

(57) ABSTRACT

A method of manufacturing an organic electroluminescent display device includes the steps of: forming transistors on an element substrate; and forming organic electroluminescent light emitting elements on the respective transistors, in which the step of forming the organic electroluminescent light emitting elements includes the steps of: forming anodes in correspondence with pixels; forming a polymer organic layer made of a polymer material by attaching the polymer material onto upper surfaces and end surfaces of the anodes; forming an organic layer having at least a light emitting layer on the polymer organic layer; and forming a cathode on the organic layer.

### CROSS-REFERENCE TO RELATED APPLICATION

The present application claims priority from Japanese application JP 2012-278537 filed on Dec. 20, 2012, the content of which is hereby incorporated by reference into this application.

### BACKGROUND OF THE INVENTION

1. Field of the Invention

The present invention relates to an organic electroluminescent display device and a method of manufacturing the organic electroluminescent display device.

2. Description of the Related Art

As thin and lightweight light emitting sources, attention has been paid to organic electroluminescence (organic light emitting diode), that is, organic electroluminescent light emitting (electroluminescent) elements, and image display devices having a large number of organic electroluminescent light emitting elements have been developed. The organic electroluminescent light emitting elements have a structure in which an organic thin film of at least one layer made of an organic material is sandwiched between each pixel electrode and a counter electrode. In recent years, an organic electroluminescent display device having the organic electroluminescent light emitting elements of this type is required to provide a higher brightness and a longer product lifetime.

The organic electroluminescent display device includes, for example, an element substrate, and a counter substrate arranged to face the element substrate. Transistors, a flattened film disposed on the transistors, and organic electroluminescent light emitting elements disposed on the flattened film, which are arranged in a matrix in correspondence with pixels, are disposed on the element substrate. Also, the transistors and the organic electroluminescent light emitting elements are electrically connected to each other through respective contact holes disposed in the flattened film. The organic electroluminescence light emitting elements disclosed in JP 2010-287543 A includes anodes (pixel electrodes), an organic layer having a light emitting layer, and a transparent cathode (counter electrode). Also, banks made of insulator are formed between the respective adjacent organic electroluminescent light emitting elements.

### SUMMARY OF THE INVENTION

In the organic electroluminescent display device having the banks of this type, a light emitting area is reduced by an increment of an area in which the banks are disposed. For that reason, a manufacturing method providing no bank between the respective organic electroluminescent light emitting elements is studied.

However, when the organic electroluminescent light emitting elements are formed without the provision of the banks, ends of the anodes are exposed without being covered with the banks. For that reason, steps are formed between the ends of the anodes and the flattened film by an increment of the thickness of the anodes. For that reason, when the organic layer and the cathode are formed on the anodes, side surfaces (end surfaces) of the ends of the anodes contact with a material of the cathode attached onto the flattened film. For that reason, short-circuiting is generated between the anodes and the cathode, resulting in a risk that the product lifetime of the organic electroluminescent light emitting elements is shortened.

The present invention has been made in view of the above circumstances, and aims at providing a method of manufacturing an organic electroluminescent display device which can realize a higher brightness and a longer product lifetime.

(1) According to the present invention, there is provided a method of manufacturing an organic electroluminescent display device, including the steps of: forming transistors on an element substrate; and forming organic electroluminescent light emitting elements on the respective transistors, in which the step of forming the organic electroluminescent light emitting elements includes the steps of forming anodes in correspondence with pixels, forming a polymer organic layer made of a polymer material by attaching the polymer material onto upper surfaces and end surfaces of the anodes; forming an organic layer having at least a light emitting layer on the polymer organic layer, and forming a cathode on the organic layer.

(2) According to the present invention, there is provided the method of manufacturing an organic electroluminescent display device according to the item (1), further including the steps of: after the step of forming the transistors and before the step of forming the organic electroluminescent light emitting elements, forming a flattened film having an insulation property which covers the transistors, and forming contact holes connecting the transistors and the anodes in the flattened film, in which the contact holes may be filled with the polymer material in the step of forming the polymer organic layer.

(3) According to the present invention, there is provided a method of manufacturing an organic electroluminescent display device, including the steps of: forming transistors on an element substrate; and forming organic electroluminescent light emitting elements on the respective transistors, in which the step of forming the organic electroluminescent light emitting elements includes the steps of forming anodes in correspondence with pixels, forming a low molecular organic layer made of a low molecular material by attaching the low molecular material onto upper surfaces and end surfaces of the anodes through oblique evaporation; forming an organic layer having at least a light emitting layer on the low molecular organic layer, and forming a cathode on the organic layer.

(4) According to the present invention, there is provided the method of manufacturing an organic electroluminescent display device according to the item (3), further including the steps of: after the step of forming the transistors and before the step of forming the organic electroluminescent light emitting elements, forming a flattened film having an insulation property which covers the transistors, and forming contact holes connecting the transistors and the anodes in the flattened film, in which the contact holes may be filled with the insulating material after the step of forming the anodes and before the step of forming the low molecular organic layer.

(5) According to the present invention, there is provided an organic electroluminescent display device including: an element substrate; transistors formed on the element substrate; and organic electroluminescent light emitting elements formed on the respective transistors, in which the respective organic electroluminescent light emitting elements include anodes formed in correspondence with pixels, a polymer organic layer made of a polymer material attached onto upper surfaces and end surfaces of the anodes; an organic layer having at least a light emitting layer, which is formed on the polymer organic layer, and a cathode covering the organic layer.

(6) According to the present invention, there is provided the organic electroluminescent display device according to the item (5), further including a flattened film having an insulation property which is formed between the transistors and the organic electroluminescent light emitting elements, and contact holes connecting the transistors and the anodes, which are formed in the flattened film, in which the contact holes may be filled with the polymer material to isolate the contact holes and the cathode from each other.

(7) According to the present invention, there is provided an organic electroluminescent display device including: an element substrate; transistors formed on the element substrate; and organic electroluminescent light emitting elements formed on the respective transistors, in which the respective organic electroluminescent light emitting elements include anodes formed in correspondence with pixels, a low molecular organic layer made of a low molecular material attached onto upper surfaces and end surfaces of the anodes, an organic layer having at least a light emitting layer, which is formed on the low molecular organic layer, and a cathode covering the organic layer.

(8) According to the present invention, there is provided the organic electroluminescent display device according to the item (7), further including a flattened film having an insulation property which is formed between the transistors and the organic electroluminescent light emitting elements, and contact holes connecting the transistors and the anodes, which are formed in the flattened film, in which the contact holes may be filled with the insulating material to isolate the contact holes and the cathode from each other.

### BRIEF DESCRIPTION OF THE DRAWINGS

FIG. 1 is a schematic plan view illustrating an organic electroluminescent display device according to a first embodiment of the present invention;

FIG. 2 is a schematic cross-sectional view taken along a line II-II of the organic electroluminescent display device illustrated in FIG. 1;

FIG. 3 is a partially enlarged view illustrating an area III of the organic electroluminescent display device illustrated in FIG. 2;

FIG. 4 is a partially enlarged view illustrating an area corresponding to the area III of the organic electroluminescent display device according to a second embodiment;

FIG. 5 is a partially enlarged view of an area corresponding to the area III illustrating a method of manufacturing the organic electroluminescent display device according to the first embodiment;

FIG. 6 is a partially enlarged view of an area corresponding to the area III illustrating a method of manufacturing the organic electroluminescent display device according to the first embodiment;

FIG. 7 is a partially enlarged view of an area corresponding to the area III illustrating a method of manufacturing the organic electroluminescent display device according to the second embodiment;

FIG. 8 is a partially enlarged view of an area corresponding to the area III illustrating a method of manufacturing the organic electroluminescent display device according to the second embodiment; and

FIG. 9 is a partially enlarged view of an area corresponding to the area III illustrating a method of manufacturing the organic electroluminescent display device according to the second embodiment.

### DETAILED DESCRIPTION OF THE INVENTION

Hereinafter, embodiments of the present invention will be described with reference to the accompanying drawings. Components described in the specification, having the same functions are denoted by identical symbols, and their description will be omitted. Also, for facilitating to understand the features, the drawings referred to in the following description may enlarge characteristic portions for convenience, and dimensional ratios of the respective components are not always identical with real dimensional ratios. Also, materials and so on exemplified in the following description are exemplary, and the respective components may be made of materials different from the exemplified materials, and can be implemented with any change without departing from the spirit thereof.

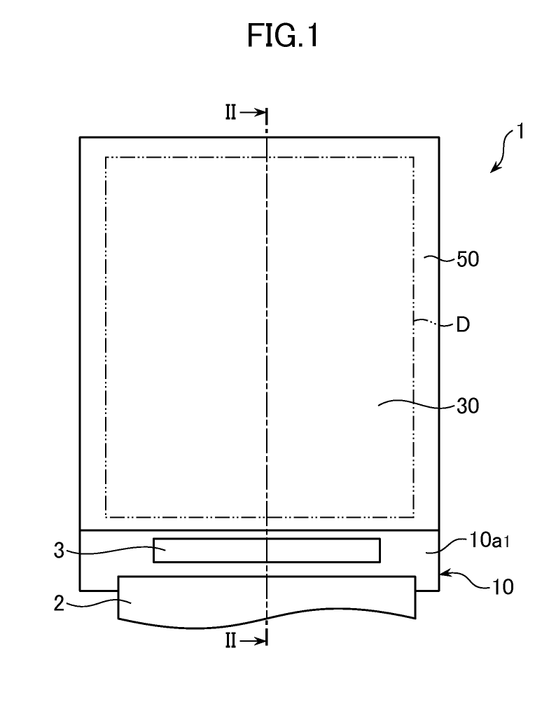

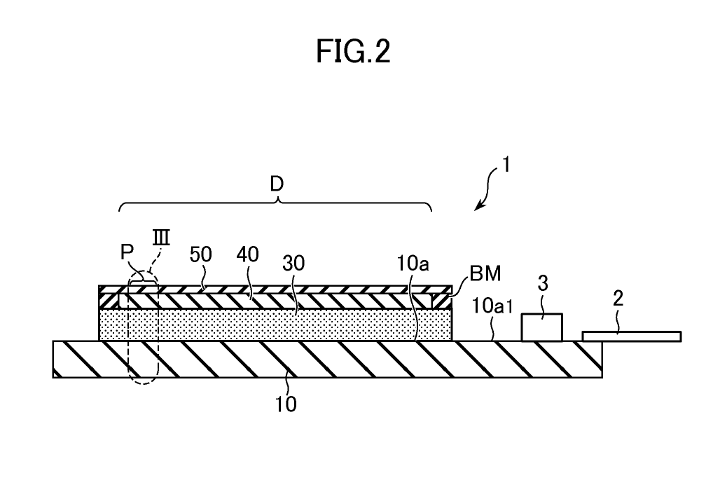

First, an organic electroluminescent display device 1 according to a first embodiment of the present invention will be described. FIG. 1 is a schematic plan view illustrating the organic electroluminescent display device 1 according to the first embodiment of the present invention, and FIG. 2 is a schematic cross-sectional view taken along a line II-II of the organic electroluminescent display device 1 illustrated in FIG. 1. The organic electroluminescent display device 1 according to this embodiment includes an element substrate 10, a flexible circuit board 2, a driving driver 3, organic electroluminescent light emitting elements 30 disposed on the element substrate 10, a sealing film 40, and a counter substrate 50.

The element substrate 10 is configured by, for example, a rectangular substrate (hereinafter referred to as low temperature polysilicon substrate) on which a low temperature polysilicon layer is formed. A plurality of the organic electroluminescent light emitting elements 30 are disposed on an upper surface 10a of the element substrate 10. The low temperature polysilicon in the present specification means polysilicon formed under a condition of 600° C. or lower. For example, the organic electroluminescent light emitting elements 30 are disposed in a display area D having an outer periphery smaller than the element substrate 10 in a plan view, and, for example, a black matrix BM formed of a light impermeable film is arranged in an area outside the display area D.

The flexible circuit board 2 is connected to an area 10a₁ in which the organic electroluminescent light emitting elements 30 are not formed, and the driving driver 3 is further disposed, in the upper surface 10a of the element substrate 10. The driving driver 3 is a driver that receives image data from an external of the organic electroluminescent display device 1 through the flexible circuit board 2. Upon receiving the image data, the driving driver 3 supplies display data to the organic electroluminescent light emitting elements 30 through data lines not shown.

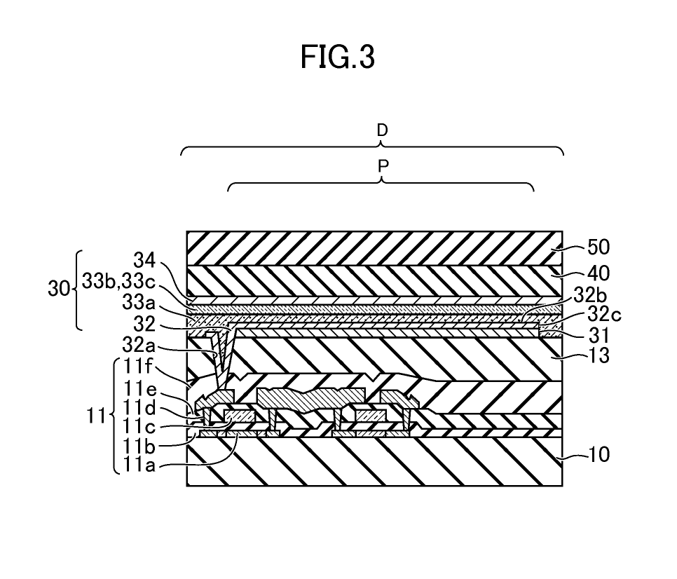

A configuration of the display area D of the organic electroluminescent display device 1 will be described in detail. FIG. 3 is a partially enlarged view illustrating an area III of the organic electroluminescent display device 1 illustrated in FIG. 2. The area III is an area corresponding to one pixel P in the display area D. A transistor (thin film transistor) 11, the organic electroluminescent light emitting element 30, the sealing film. 40, and the counter substrate 50 are laminated on the element substrate 10 of the area III.

The thin film transistor 11 is a transistor for driving the organic electroluminescent light emitting element 30, and disposed on the element substrate 10 for each of the pixels P. The thin film transistor 11 includes, for example, a polysilicon semiconductor layer 11a, a gate insulating film 11b, a gate line (gate electrode) 11c, a source/drain electrode 11d, a first insulating film 11e, and a second insulating film 11f.

A flattened film 13 having an insulation property is formed on the thin film transistor 11 so as to cover the thin film transistor 11. The flattened film 13 is made of, for example, SiO₂, SiN, acrylic, or polyimide. With the provision of the flattened film 13 on the thin film transistor 11, electric isolation is performed between the adjacent thin film transistors 11, and between the thin film transistors 11 and the organic electroluminescent light emitting elements 30.

A reflective film 31 is disposed in an area corresponding to each pixel P on the flattened film 13. The reflective film 31 is disposed to reflect a light emitted from the organic electroluminescent light emitting element 30 toward the sealing film 40 side. The reflective film 31 is preferably higher in the optical reflectivity, and can be formed of a metal film made of, for example, aluminum or silver (Ag).

The organic electroluminescent light emitting elements 30 are disposed on the flattened film 13 through, for example, the reflective films 31. The organic electroluminescent light emitting elements 30 are roughly each configured by an anode 32 formed on the flattened film 13 (reflective film 31), a polymer organic layer 33a, an organic layer 33b having at least a light emitting layer 33c, and a cathode 34 formed to cover the organic layer 33b.

The anodes 32 are formed in correspondence with the respective pixels P in a matrix. The anodes 32 are made of, for example, a translucent and conductive material such as ITO (indium tin oxide), and formed to cover the reflective film 31. The reflective film 31 is configured by a part of the anode 32 if the reflective film 31 is made of metal such as silver, and contacts with the anode 32.

The anode 32 is electrically connected to the thin film transistor 11 through a contact hole 32a formed in the flattened film 13. With the above configuration, a drive current supplied from the thin film transistor 11 is injected into the polymer organic layer 33a and the organic layer 33b through the anode 32.

The polymer organic layer 33a is made of a polymer material attached to an upper surface 32b and an end surface 32c of the anode 32. The polymer material is attached to an overall surface of the end surface 32c to prevent a contact of the adjacent anodes 32, and a contact of the anode 32 and the cathode 34. The polymer organic layer 33a may have, for example, a function of a hole injection layer or a hole transport layer for transferring holes (positive holes) injected from the anode 32 to the light emitting layer.

Also, the polymer material is attached to a surface of the flattened film 13 to form the polymer organic layer 33a also on the flattened film 13. With the above configuration, the contact between the adjacent anodes 32 is prevented.

The end surface 32c of this embodiment means a side surface of an outer periphery of the anode 32 when viewed from a direction of the counter substrate 50. As long as the polymer organic layer 33a is made of a polymer material and a current from the anode 32 can be fed to the organic layer 33b, a material of the polymer organic layer 33a is not limited. Also, when the reflective film 31 made of metal is configured to contact with the anode 32, it is preferable that the polymer material is attached to the overall end surface of the reflective film 31.

Also, the contact hole 32a is filled with the polymer material of the polymer organic layer 33a. With this configuration, the contact hole 32a is isolated from the cathode 34.

The organic layer 33b is formed to cover the polymer organic layer 33a. The organic layer 33b is formed by, for example, laminating the light emitting layer 33c, an electron transport layer not shown, and an electron injection layer not shown in the stated order from the anode 32 side. A laminated structure of the organic layer 33b is not limited to this configuration, and the laminated structure is not specified if the laminated structure has at least the light emitting layer 33c. Also, the organic layer 33b may be of a laminated structure of layers made of a low molecular material, a laminated structure of layers made of a polymer material, or the combination of those layers.

The light emitting layer 33c is made of, for example, an organic electroluminescent material that emits a light by coupling positive holes and electrons together. The light emitting layer 33c may emit a white light, or emit a light of another color.

The cathode 34 is formed to cover the organic layer 33b (light emitting layer 33c). The cathode 34 is a transparent common electrode that commonly contacts with the organic layer 33b of the plural organic electroluminescent light emitting elements 30. The cathode 34 is made of, for example, a translucent or conductive material such as ITO.

An upper surface of the cathode 34 is covered with the sealing film 40. The sealing film 40 preferably has, for example, a silicon nitride (SiN) layer, but may have, for example, an SiO layer, an SiON layer, or a resin layer. Also, the sealing film 40 may be formed of a single-layer film made of those materials, or a laminated structure.

An upper surface of the sealing film 40 is covered with, for example, the counter substrate 50. The counter substrate 50 is formed of, for example, a glass substrate having an outer periphery smaller than the element substrate 10 in a plan view, and disposed to face the element substrate 10 through the sealing film 40. Instead of the counter substrate 50, a membranous protective film that protects a surface of the sealing film 40 may be formed on the sealing film 40.

In the organic electroluminescent display device 1 according to this embodiment, the polymer organic layer 33a is made of the polymer material attached to the end surface 32c of the anode 32. As a result, even if no bank is formed between the adjacent anodes 32, the end surface 32c of the anode 32 is prevented from contacting with the cathode 34. For that reason, as compared with the organic electroluminescent display device without this configuration, the light emitting area is large, and the short-circuiting of the anode 32 and the cathode 34 can be prevented from occurring. With the above configuration, the higher brightness and the longer product lifetime of the organic electroluminescent display device 1 can be realized.

Also, in the organic electroluminescent display device 1 according to this embodiment, the contact of the contact hole 32a and the cathode 34 is prevented by the polymer material with which the contact hole 32a is filled. For that reason, as compared with the organic electroluminescent display device without this configuration, the short-circuiting of the contact hole 32a and the cathode 34 can be prevented from occurring, and the longer product lifetime can be realized.

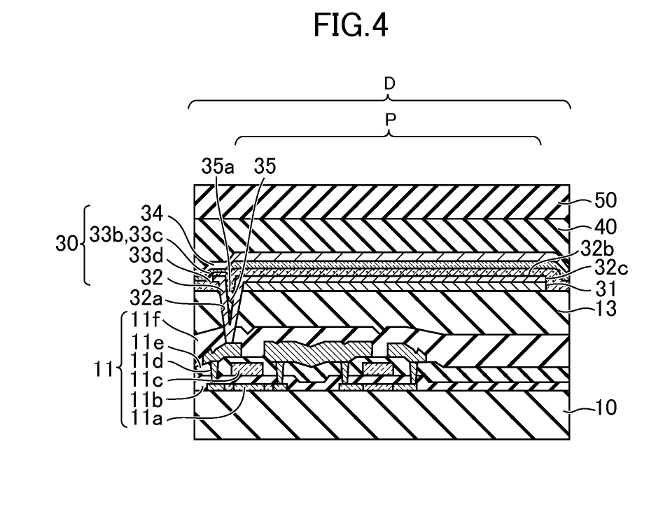

Subsequently, the organic electroluminescent display device 1 according to a second embodiment will be described. FIG. 4 is a partially enlarged view illustrating an area corresponding to the area III of the organic electroluminescent display device 1 according to the second embodiment. The organic electroluminescent display device 1 according to the second embodiment is different from the organic electroluminescent display device 1 according to the first embodiment in that the contact hole 32a is filled with an insulating material 35, the upper surface 32b and the end surface 32c of the anode 32 are covered with a low molecular organic layer 33d made of a low molecular material which is attached to the upper surface 32b and the end surface 32c, and the organic layer 33b is formed to cover the low molecular organic layer 33d. Hereinafter, a configuration of the insulating material 35 and the low molecular organic layer 33d will be described, and the same configuration as that of the organic electroluminescent display device 1 according to the first embodiment will be omitted from description.

The contact hole 32a is filled with the insulating material 35. It is preferable that an upper surface 35a of the insulating material 35 is located below the upper surface 32b of the anode 32, and located closer to the upper surface 32b. The insulating material 35 is not limited to any material if the insulating material 35 has an insulation property, and can isolate the contact hole 32a and the cathode 34 from each other. With the above configuration, the contact of the contact hole 32a and the cathode 34 is prevented.

The low molecular organic layer 33d is made of the low molecular material attached to the upper surface 32b and the end surface 32c of the anode 32. The low molecular material is attached to the overall end surface 32c, to thereby prevent the contact of the adjacent anodes 32, and the contact of the anode 32 and the cathode 34.

Also, the low molecular material is attached to a surface of the flattened film 13 to also form the low molecular organic layer 33d on the flattened film 13. With the above configuration, the contact of the adjacent anodes 32 with each other is prevented.

As long as the low molecular organic layer 33d is made of the low molecular material, and a current from the anode 32 can be fed to the organic layer 33b (light emitting layer 33c), a material of the low molecular organic layer 33d is not limited. Also, the low molecular organic layer 33d may have, for example, a function of the hole injection layer and the hole transport layer for transferring the holes (positive holes) injected from the anode 32 to the light emitting layer. Also, when the reflective film 31 made of metal is configured to contact with the anode 32, it is preferable that the low molecular material is attached to the overall end surface of the reflective film 31.

The low molecular organic layer 33d is covered with the organic layer 33b having at least the light emitting layer 33c. Also, the cathode 34, the sealing film 40, and the counter substrate 50 are laminated on the organic layer 33b.

In the organic electroluminescent display device 1 according to this embodiment, the low molecular material is attached onto the end surface 32c of the anode 32, to thereby form the low molecular organic layer 33d. With this configuration, even if no bank is formed between the adjacent anodes 32, the contact of the end surface 32c of the anode 32 and the cathode 34 is prevented. For that reason, as compared with the organic electroluminescent display device without this embodiment, the light emitting area can be widely ensured, and the short-circuiting of the anode 32 and the cathode 34 can be prevented from occurring. With the above configuration, the higher brightness and the longer product lifetime of the organic electroluminescent display device 1 can be realized.

Also, in the organic electroluminescent display device 1 according to this embodiment, the contact of the contact hole 32a and the cathode 34 is prevented by the insulating material 35 with which the contact hole 32a is filled. For that reason, the short-circuiting of the contact hole 32a and the cathode 34 can be prevented from occurring. Also, since the upper surface 35a of the insulating material 35 is covered with the low molecular organic layer 33d, the short-circuiting of the contact hole 32a and the organic layer 33b can be prevented from occurring. For that reason, as compared with the organic electroluminescent display device without this configuration, the longer product lifetime can be realized.

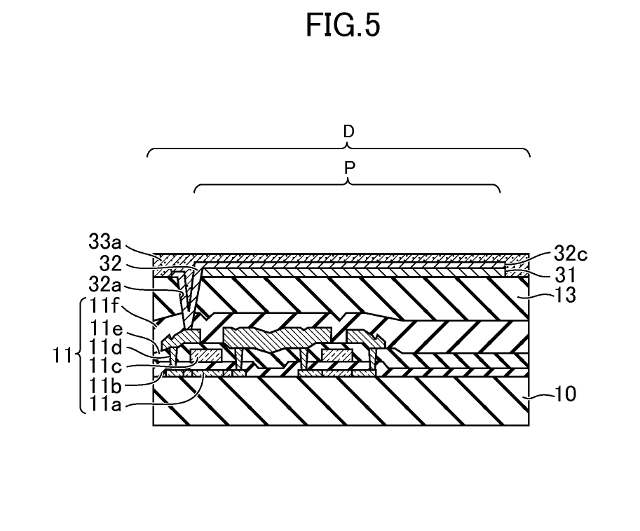

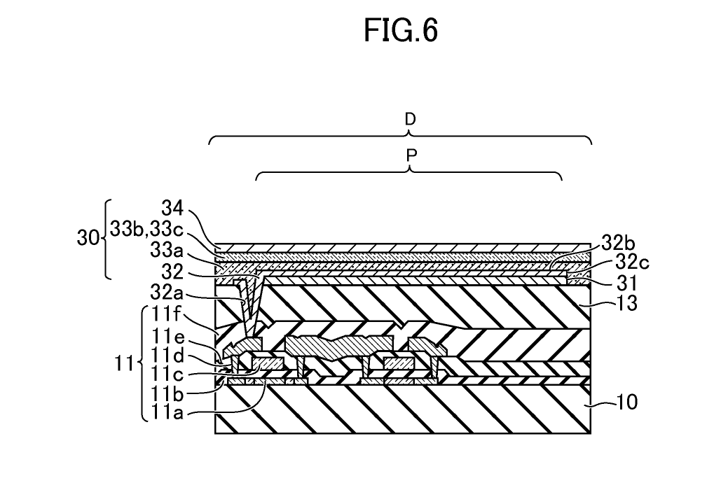

Subsequently, a method of manufacturing the organic electroluminescent display device 1 according to the first embodiment of the present invention will be described with reference to the accompanying drawings. FIGS. 5 and 6 are partially enlarged views of an area corresponding to the area III illustrating the method of manufacturing the organic electroluminescent display device according to the first embodiment.

The method of manufacturing the organic electroluminescent display device 1 according to this embodiment includes a step of forming the thin film transistors 11 on the element substrate 10, a step of forming the flattened film 13, a step of forming the contact holes 32a, a step of forming the organic electroluminescent light emitting elements 30, a step of forming the sealing film 40, and a step of arranging the counter substrate 50.

First, the thin film transistor 11 is formed on the element substrate 10. First, for example, the element substrate 10 which is a rectangular low temperature polysilicon substrate is prepared. Then, the polysilicon semiconductor layer 11a, the gate insulating film 11b, the gate line (gate electrode) 11c, the source/drain electrode 11d, the first insulating film 11e, the second insulating film 11f, and the like are laminated on each display area D of the element substrate 10, to thereby form the thin film transistor 11.

Subsequently, the flattened film 13 having the insulation property is formed to cover the thin film transistor 11. The flattened film 13 can be made of, for example, SiO₂, SiN, acrylic, or polyimide. Then, the contact holes 32a from which the source/drain electrode 11d of the thin film transistor 11 is exposed are formed. Thereafter, the reflective film 31 formed of a metal film made of aluminum, silver (Ag), or the like is formed in an area corresponding to each pixel P on the flattened film 13.

Then, the organic electroluminescent light emitting elements 30 are formed in the area corresponding to each pixel P on the flattened film 13 (reflective film 31). The step of forming the organic electroluminescent light emitting elements 30 includes a step of forming the anode 32, a step of forming the polymer organic layer 33a, a step of forming the organic layer 33b having at least the light emitting layer 33c, and a step of forming the cathode 34.

First, the anodes 32 made of, for example, the translucent and conductive material such as ITC are formed to cover the flattened film 13 (reflective film 31) in correspondence with the respective pixels P. With this configuration, the anodes 32 are electrically connected to the thin film transistor 11 through the contact holes 32a. When the anodes 32 are formed to contact with the upper surface of the reflective film 31 made of metal, the reflective film 31 forms a part of each anode 32.

Then, a polymer material is attached to the upper surface 32b and the overall end surface 32c of the anode 32 through, for example, an inkjet technique, to thereby form the polymer organic layer 33a made of polymer material. As a result, the contact of the adjacent anodes 32, and the contact of the anode 32 and the cathode 34 are prevented.

Also, the polymer material is also attached to the surface of the flattened film 13, to thereby form the polymer organic layer 33a on the flattened film 13. As a result, the contact of the adjacent anodes 32 are prevented. Also, when the reflective film 31 made of metal is configured to contact with the anode 32, it is preferable that the polymer material is attached to the overall end surface of the reflective film 31.

The polymer organic layer 33a may have, for example, a function of the hole injection layer and the hole transport layer for transferring the holes (positive holes) injected from the anode 32 to the light emitting layer 33c. Also, if the polymer material can feed a current from the anode 32 to the organic layer 33b, the polymer material is not limited.

It is preferable that when the polymer organic layer 33a is formed, the contact hole 32a is filled with the polymer material which is a material of the polymer organic layer 33a.

Then, as illustrated in FIG. 6, the organic layer 33b having at least the light emitting layer 33c is formed to cover the polymer organic layer 33a. As a method of forming the organic layer 33b, there can be employed a method of depositing the low molecular organic material on the polymer organic layer 33a through, for example, a vacuum deposition method.

The organic layer 33b is formed by laminating, for example, the light emitting layer 33c, an electron transport layer, and an electron injection layer in order from the anode 32 side. A laminated structure of the organic layer 33b is not limited to this configuration, and the laminated structure is not specified if the laminated structure has at least the light emitting layer 33c. Also, the organic layer 33b may be formed by laminating layers made of a low molecular material, by laminating layers made of a polymer material, or by the combination of those layers.

Then, the cathode 34 made of, for example, the translucent and conductive material such as ITO is formed to cover the organic layer 33b (light emitting layer 33c). With the above process, the organic electroluminescent light emitting elements 30 are formed.

Then, the sealing film 40 having, for example, a silicon nitride (SiN) layer is formed to cover the upper surface of the organic electroluminescent light emitting elements 30 (cathode 34). Then, the counter substrate 50 formed of, for example, a glass substrate is arranged to cover the upper surface of the sealing film 40. The counter substrate 50 according to this embodiment has an outer periphery smaller than the element substrate 10 in a plan view. Instead of the counter substrate 50, a membranous protective film that protects the surface of the sealing film 40 may be formed on the sealing film 40.

Thereafter, with the provision of the flexible circuit board 2 and the driving driver 3 in FIG. 1 on the upper surface of the element substrate 10, the organic electroluminescent display device 1 according to this embodiment is formed.

In the method of manufacturing the organic electroluminescent display device 1 according to this embodiment, the polymer material is attached to the overall end surface 32c of the anode 32, to thereby form the polymer organic layer 33a. With the above process, the contact between the end surface 32c of the anode 32 and the cathode 34 can be prevented without forming the bank between the adjacent anodes 32. For that reason, as compared with the method of manufacturing the organic electroluminescent display device without this process, there can be manufactured the organic electroluminescent display device 1 that is large in the light emitting area, and can prevent the occurrence of the short-circuiting between the anodes 32 and the cathode 34. With the above processing, the higher brightness and the longer product lifetime of the organic electroluminescent display device 1 can be realized.

Also, in the method of manufacturing the organic electroluminescent display device 1 according to this embodiment, since the contact hole 32a is filled with the polymer material, the short-circuiting of the contact hole 32a and the cathode 34 can be prevented from occurring. For that reason, as compared with the method of manufacturing the organic electroluminescent display device without this process, the longer product lifetime of the organic electroluminescent display device 1 can be realized.

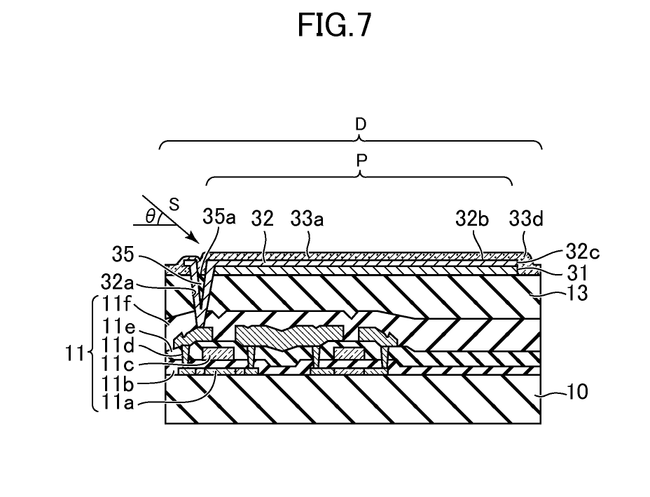

Then, a method of manufacturing the organic electroluminescent display device 1 according to a second embodiment of the present invention will be described with reference to the accompanying drawings. FIGS. 7 to 9 are partially enlarged views of an area corresponding to the area III illustrating the method of manufacturing the organic electroluminescent display device 1 according to the second embodiment.

The method of manufacturing the organic electroluminescent display device 1 according to the second embodiment is different from the method of manufacturing the organic electroluminescent display device 1 according to the first embodiment in that there are provided a step of filling the contact hole 32a with the insulating material 35, and a step of forming the low molecular organic layer 33d made of the low molecular material. Hereinafter, the step of forming the low molecular organic layer 33d, and the step of filling the contact hole 32a with the insulating material 35 will be described, and the same steps as those in the method of manufacturing the organic electroluminescent display device 1 according to the first embodiment will be omitted from the detailed description.

First, as in the method of manufacturing the organic electroluminescent display device 1 according to the first embodiment, the thin film transistor 11, the flattened film 13, the reflective films 31, and the anode 32 are sequentially formed on the element substrate 10. Those steps are identical with those in the method of manufacturing the organic electroluminescent display device 1 according to the first embodiment, and therefore their detailed description will be omitted.

Then, as illustrated in FIG. 7, the contact hole 32a is filled with the insulating material 35 through, for example, the inkjet technique. It is preferable that the filling amount of the insulating material 35 is appropriately set so that the upper surface 35a of the insulating material 35 is located below the upper surface 32b of the anode 32, and located closer to the upper surface 32b. Also, the method of filling with the insulating material 35 is not limited to the inkjet technique, but may use other method. The insulating material 35 is not limited if the insulating material 35 has an insulation property.

Then, the low molecular material is attached onto the upper surface 32b of the anode 32 and the overall surface of the end surface 32c through an oblique evaporation from an evaporation direction S, to thereby form the low molecular organic layer 33d made of the low molecular material. Also, the low molecular material is attached onto the surface of the flattened film 13, to thereby also form the low molecular organic layer 33d on the flattened film 13.

When it is assumed that an angle formed between the evaporation direction S and the upper surface 32b of the anode 32 is an angle θ, the angle θ becomes an acute angle (θ<90°. A value of the angle θ may be appropriately set according to a thickness of the anode 32 so that the low molecular material is attached to the overall surface of the end surface 32c. Also, when the reflective film 31 made of metal is configured to contact with the anode 32, it is preferable that the low molecular material is attached to the overall end surface of the reflective film 31. Also, in this process, the oblique evaporation may be conducted while rotating the element substrate 10.

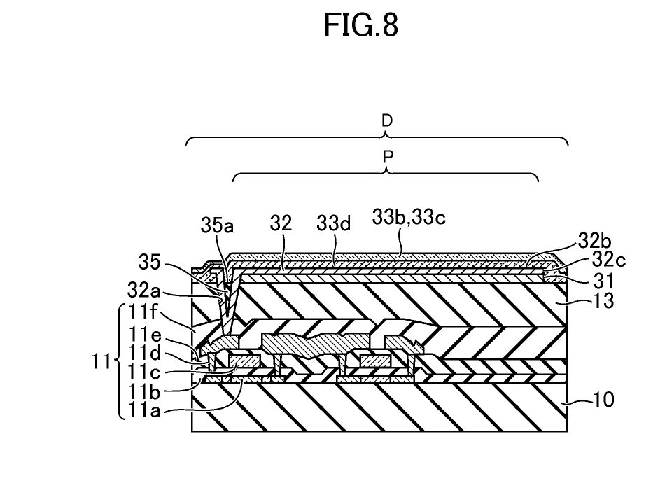

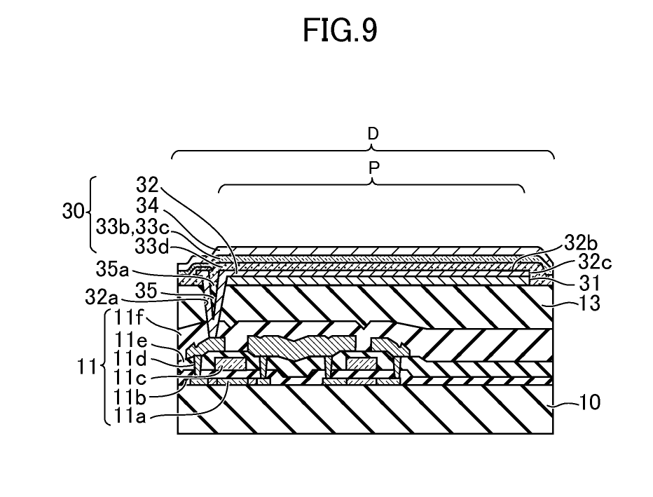

Then, as illustrated in FIG. 8, the organic layer 33b having at least the light emitting layer 33c is formed to cover the low molecular organic layer 33d. Then, as illustrated in FIG. 9, the cathode 34 is formed to cover the organic layer 33b (light emitting layer 33c). With the above process, the organic electroluminescent light emitting elements 30 are formed.

Thereafter, the sealing film 40 and the counter substrate 50 are formed, and the flexible circuit board 2 and the driving driver 3 illustrated in FIG. 1 are disposed on the upper surface of the element substrate 10, to thereby form the organic electroluminescent display device 1 according to this embodiment.

In the method of manufacturing the organic electroluminescent display device 1 according to this embodiment, the low molecular material is attached to the end surface 32c of the anode 32, to thereby form the low molecular organic layer 33d. With this process, the contact of the end surface 32c of the anode 32 and the cathode 34 can be prevented without forming the bank between the adjacent anodes 32. For that reason, as compared with the method of manufacturing the organic electroluminescent display device without this process, there can be manufactured the organic electroluminescent display device 1 that is large in the light emitting area, and can prevent the occurrence of the short-circuiting between the anodes 32 and the cathode 34. With the above processing, the higher brightness and the longer product lifetime of the organic electroluminescent display device 1 can be realized.

Also, in the method of manufacturing the organic electroluminescent display device 1 according to this embodiment, since the contact hole 32a is filled with the insulating material 35, the short-circuiting between the contact hole 32a and the cathode 34 can be prevented from occurring. For that reason, as compared with the method of manufacturing the organic electroluminescent display device without this process, the longer product lifetime of the organic electroluminescent display device 1 can be realized.

Also, in this process, the oblique evaporation is conducted while rotating the element substrate 10 with the results that the amount of low molecular material attached to the end surface 32c of the anode 32 becomes larger than that in the method of manufacturing the organic electroluminescent display device without this process. For that reason, as compared with the method of manufacturing the organic electroluminescent display device 1 without this configuration, the low molecular organic layer 33d formed on the end surface 32c is thickened, and the short-circuiting of the end surface 32c of the anode 32 and the cathode 34 can be more surely prevented from occurring.

While there have been described what are at present considered to be certain embodiments of the invention, it will be understood that various modifications may be made thereto, and it is intended that the appended claim cover all such modifications as fall within the true spirit and scope of the invention.

What is claimed is:

1. A method of manufacturing an organic electroluminescent display device, comprising the steps of:
forming transistors on an element substrate; and
forming organic electroluminescent light emitting elements on the respective transistors,
wherein the step of forming the organic electroluminescent light emitting elements includes the steps of:
forming anodes in correspondence with pixels;
forming a polymer organic layer made of a polymer material by attaching the polymer material onto upper surfaces and end surfaces of the anodes;
forming an organic layer having at least a light emitting layer on the polymer organic layer; and
forming a cathode on the organic layer.

2. The method of manufacturing an organic electroluminescent display device according to claim 1, further comprising the steps of: after the step of forming the transistors and before the step of forming the organic electroluminescent light emitting elements,
forming a flattened film having an insulation property which covers the transistors; and
forming contact holes connecting the transistors and the anodes in the flattened film,
wherein the contact holes are filled with the polymer material in the step of forming the polymer organic layer.

3. A method of manufacturing an organic electroluminescent display device, comprising the steps of:
forming transistors on an element substrate; and
forming organic electroluminescent light emitting elements on the respective transistors,
wherein the step of forming the organic electroluminescent light emitting elements includes the steps of:
forming anodes in correspondence with pixels;
forming a low molecular organic layer made of a low molecular material by attaching the low molecular material onto upper surfaces and end surfaces of the anodes through oblique evaporation;
forming an organic layer having at least a light emitting layer on the low molecular organic layer; and
forming a cathode on the organic layer.

4. The method of manufacturing an organic electroluminescent display device according to claim 3, further comprising the steps of: after the step of forming the transistors and before the step of forming the organic electroluminescent light emitting elements,
forming a flattened film having an insulation property which covers the transistors, and
forming contact holes connecting the transistors and the anodes in the flattened film,
wherein the contact holes are filled with the insulating material after the step of forming the anodes and before the step of forming the low molecular organic layer.

5. An organic electroluminescent display device comprising:
an element substrate;
transistors formed on the element substrate; and
organic electroluminescent light emitting elements formed on the respective transistors,
wherein the respective organic electroluminescent light emitting elements include:
anodes formed in correspondence with pixels;
a polymer organic layer made of a polymer material attached onto upper surfaces and end surfaces of the anodes;
an organic layer having at least a light emitting layer, which is formed on the polymer organic layer; and
a cathode covering the organic layer.

6. The organic electroluminescent display device according to claim 5, further comprising:
a flattened film having an insulation property, which is formed between the transistors and the organic electroluminescent light emitting elements; and
contact holes connecting the transistors and the anodes, which are formed in the flattened film,
wherein the contact holes are filled with the polymer material to isolate the contact holes and the cathode from each other.

7. An organic electroluminescent display device comprising:
an element substrate;
transistors formed on the element substrate; and
organic electroluminescent light emitting elements formed on the respective transistors,
wherein the respective organic electroluminescent light emitting elements include:
anodes formed in correspondence with pixels, a low molecular organic layer made of a low molecular material attached onto upper surfaces and end surfaces of the anodes;
an organic layer having at least a light emitting layer, which is formed on the low molecular organic layer; and
a cathode covering the organic layer.

8. The organic electroluminescent display device according to claim 7, further comprising:
a flattened film having an insulation property which is formed between the transistors and the organic electroluminescent light emitting elements; and
contact holes connecting the transistors and the anodes, which are formed in the flattened film,
wherein the contact holes are filled with the insulating material to isolate the contact holes and the cathode from each other.
